(19) United States
(12) Patent Application Publication
(10) Pub. No.: US 2013/0161667 A1
(43) Pub. Date: Jun. 27, 2013

(54) PATTERNED REFLECTIVE LAYER ON DIELECTRIC LAYER FOR LED ARRAY

(71) Applicants: Chia-Nan Chen, Zhubei City (TW); Yi-An Lu, Chiayi City (TW)

(72) Inventors: Chia-Nan Chen, Zhubei City (TW); Yi-An Lu, Chiayi City (TW)

(73) Assignee: PHOSTEK, INC., Taipei City (TW)

(21) Appl. No.: 13/333,375

(22) Filed: Dec. 21, 2011

(51) Int. Cl. H01L 33/60

(52) U.S. Cl. 257/91; 438/27; 257/E33.06

(57) ABSTRACT

A light emitting diode array includes a first light emitting diode with a first electrode and a second light emitting diode with a second electrode. A first dielectric layer is positioned between the light emitting diodes. A first portion of the first dielectric layer at least partially covers the first light emitting diode and a second portion of the first dielectric layer at least partially covers the second light emitting diode. An interconnect is located at least partially on the first dielectric layer. The interconnect connects the first electrode to the second electrode. A reflective layer is formed over at least the first and second portions of the first dielectric layer. A permanent substrate is coupled to a side of the light emitting diodes having the reflective layer.

### BACKGROUND

1. Field of the Invention

The present invention relates to a semiconductor light emitting component, and more particularly to a light emitting diode (LED) array and a method for manufacturing the LED array.

2. Description of Related Art

FIG. 1 illustrates a schematic view of a conventional horizontal light emitting diode. Referring to FIG. 1, horizontal light emitting diode 100 includes epitaxial substrate 102. Epitaxial structure 104 is grown from the epitaxial substrate by an epitaxial growth process. Electrode unit 106 is formed on the epitaxial structure for providing electrical energy. Epitaxial substrate 102 is made of a material such as sapphire or SiC so that epitaxial growth of group-III nitride (e.g., gallium-nitride-based (GaN-based) or indium-gallium-nitride-based (InGaN-based) semiconductor material) can be achieved on epitaxial substrate 102.

Epitaxial structure 104 is usually made of GaN-based semiconductor material or InGaN-based semiconductor material. During the epitaxy growth process, GaN-based semiconductor material or InGaN-based semiconductor material epitaxially grows up from epitaxial substrate 102 to form n-type doped layer 108 and p-type doped layer 110. When the electrical energy is applied to epitaxial structure 104, light emitting portion 112 at junction of n-type doped layer 108 and p-type doped layer 110 generates an electron-hole capture phenomenon. As a result, the electrons of light emitting portion 112 will fall to a lower energy level and release energy with a photon mode. For example, light emitting portion 112 is a single quantum well (SQW) or a multiple quantum well (MQW) structure capable of restricting a spatial movement of the electrons and the holes. Thus, a collision probability of the electrons and the holes is increased so that the electron-hole capture phenomenon occurs easily, thereby enhancing light emitting efficiency.

Electrode unit 106 includes first electrode 114 and second electrode 116. First electrode 114 and second electrode 116 are in ohmic contact with n-type doped layer 108 and p-type doped layer 110, respectively. The electrodes are configured to provide electrical energy to epitaxial structure 104. When a voltage is applied between first electrode 114 and second electrode 116, an electric current flows from the second electrode to the first electrode through epitaxial structure 104 and is horizontally distributed in epitaxial structure 104. Thus, a number of photons are generated by a photoelectric effect in epitaxial structure 104. Horizontal light emitting diode 100 emits light from epitaxial structure 104 due to the horizontally distributed electric current.

A manufacturing process of horizontal light emitting diode 100 is simple. However, horizontal light emitting diodes can cause several problems such as, but not limited to, current crowding problems, non-uniformity light emitting problems, and thermal accumulation problems. These problems may decrease the light emitting efficiency of the horizontal light emitting diode and/or damage the horizontal light emitting diode.

To overcome some of the above mentioned problems, vertical light emitting diodes have been developed. FIG. 2 depicts a schematic view of a conventional vertical light emitting diode. Vertical light emitting diode 200 includes epitaxial structure 204 and electrode unit 206 disposed on the epitaxial structure for providing electrical energy. Similar to horizontal light emitting diode 100 shown in FIG. 1, epitaxial structure 204 can be made of GaN-based semiconductor material or InGaN-based semiconductor material by an epitaxial growth process. During the epitaxial growth process, the GaN-based semiconductor material and the InGaN-based semiconductor material epitaxially grows up from an epitaxial substrate (not shown) to form n-type doped layer 208, light emitting structure 212, and p-type doped layer 210. Then, electrode unit 206 is bonded to epitaxial structure 204 after stripping the epitaxial substrate. Electrode unit 206 includes first electrode 214 and second electrode 216. First electrode 214 and second electrode 216 are in ohmic contact with n-type doped layer 208 and p-type doped layer 210, respectively. In addition, second electrode 216 can adhere to heat dissipating substrate 202 so as to increase the heat dissipation efficiency. When a voltage is applied between first electrode 214 and second electrode 216, an electric current vertically flows. Thus, conventional vertical light emitting diode 200 can effectively improve the current crowding problem, the non-uniformity light emitting problem and the thermal accumulation problem of horizontal light emitting diode 100. However, a shading effect of the electrodes is a problem in the conventional vertical light emitting diode depicted in FIG. 2. In addition, the manufacturing process for forming vertical light emitting diode 200 may be complicated. For example, epitaxial structure 204 may be damaged by high heat when adhering second electrode 216 to heat dissipating substrate 202.

In recent years, wide-bandgap nitride-based LEDs with wavelength range from the ultraviolet to the shorter wavelength parts of the visible spectra have been developed. LED devices can be applied to new display technologies such as traffic signals, liquid crystal display TVs, and backlights of cell phones. Due to the lack of native substrates, GaN films and related nitride compounds are commonly grown on sapphire wafers. Conventional LEDs (such as those described above) are inefficient because the photons are emitted in all directions. A large fraction of light emitted is limited in the sapphire substrate and cannot contribute to usable light output. Moreover, the poor thermal conductivity of the sapphire substrate is also a problem associated with conventional nitride LEDs. Therefore, freestanding GaN optoelectronics without the use of sapphire is a desirable technology that solves this problem. The epilayer transferring technique is a well-known innovation in achieving ultrabright LEDs. Thin-film p-side-up GaN LEDs with highly reflective reflector on silicon substrate made by a laser lift-off (LLO) technique, combined with n-GaN surface roughening, have been established as an effective tool for nitride-based heteroepitaxial structures to eliminate the sapphire constraint. The structure is regarded as a good candidate for enhancing the light extraction efficiency of GaN-based LEDs. However, this technique is also subject to the electrode-shading problem. The emitted light is covered and absorbed by the electrodes, which results in reduced light efficiency.

Thin-film n-side-up devices GaN LEDs with interdigitated imbedded electrodes may improve light emission by reducing some of the electrode-shading problem. While thin-film n-side-up devices GaN LEDs provide enhanced properties compared to thin-film p-side-up devices GaN LEDs, there is still a need for improved structures and processes for making both p-side-up and n-side-up devices.

Furthermore, horizontal light emitting diode 100 and vertical light emitting diode 200 typically are packaged in single-die manners, which does not facilitate manufacturing a large area light source. In view of the problems discussed above with reference to FIG. 1 and FIG. 2, there is a need for light emitting diodes and manufacturing methods that overcome the above disadvantages of the horizontal light emitting diodes and the vertical light emitting diodes and facilitates manufacturing large area light sources on a single substrate.

### SUMMARY

In certain embodiments, a light emitting diode array includes a first light emitting diode with a first electrode and a second light emitting diode with a second electrode. A first dielectric layer is positioned between the first light emitting diode and the second light emitting diode. A first portion of the first dielectric layer at least partially covers the first light emitting diode and a second portion of the first dielectric layer at least partially covers the second light emitting diode. An interconnect is located at least partially on the first dielectric layer. The interconnect connects the first electrode to the second electrode. A reflective layer is formed over at least the first and second portions of the first dielectric layer. A permanent substrate is coupled to a side of the light emitting diodes comprising the first and second reflective layers.

In certain embodiments, a method for forming a light emitting diode array includes forming a first light emitting diode and a second light emitting diode on a temporary substrate. A first dielectric layer is formed between the first light emitting diode and the second light emitting diode. A first portion of the first dielectric layer at least partially covers the first light emitting diode and a second portion of the first dielectric layer at least partially covers the second light emitting diode. An interconnect is formed between a first electrode on the first light emitting diode and a second electrode on the second light emitting diode. The interconnect is formed at least partially on the first dielectric layer. A reflective layer is formed over at least the first and second portions of the first dielectric layer. A permanent substrate is coupled to a side of the light emitting diodes having the reflective layer. The temporary substrate is removed from the light emitting diodes.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 illustrates a schematic view of a conventional horizontal light emitting diode.

FIG. 2 illustrates a schematic view of a conventional vertical light emitting diode.

FIG. 3 depicts a cross-sectional view of an embodiment of LEDs formed on a first substrate with dielectric material covering and between the LEDs.

FIG. 3A depicts a representation of one possible embodiment of an LED.

FIG. 4 depicts a cross-sectional view of an embodiment of LEDs formed on a first substrate with dielectric material covering and between the LEDs and a patterned mask over the dielectric material.

FIG. 5 depicts a cross-sectional view of an embodiment of LEDs formed on a first substrate with a first dielectric layer between the LEDs and interconnects between the LEDs.

FIG. 6 depicts a cross-sectional view of the embodiment of FIG. 5 with an adhesive layer bonded to the LEDs.

FIG. 7 depicts a cross-sectional view of the embodiment of FIG. 6 with a second substrate bonded to the adhesive layer.

FIG. 8 depicts a cross-sectional view of the embodiment of FIG. 7 with the first substrate removed.

FIG. 9 depicts a cross-sectional view of an embodiment of an LED array with individual reflective layers formed over individual LEDs.

FIG. 10 depicts a schematic, top view of an embodiment of an LED array with individual reflective layers formed over individual LEDs.

FIG. 11 depicts a schematic, top view of an embodiment of an LED array with a single reflective layer formed over the plurality of LEDs in the LED array.

FIG. 12 depicts a cross-sectional view of an embodiment of an LED array with an adhesive layer formed over individual reflective layers with the adhesive layer bonded to a second substrate.

FIG. 13 depicts a cross-sectional view of the embodiment of FIG. 12 with the first substrate removed.

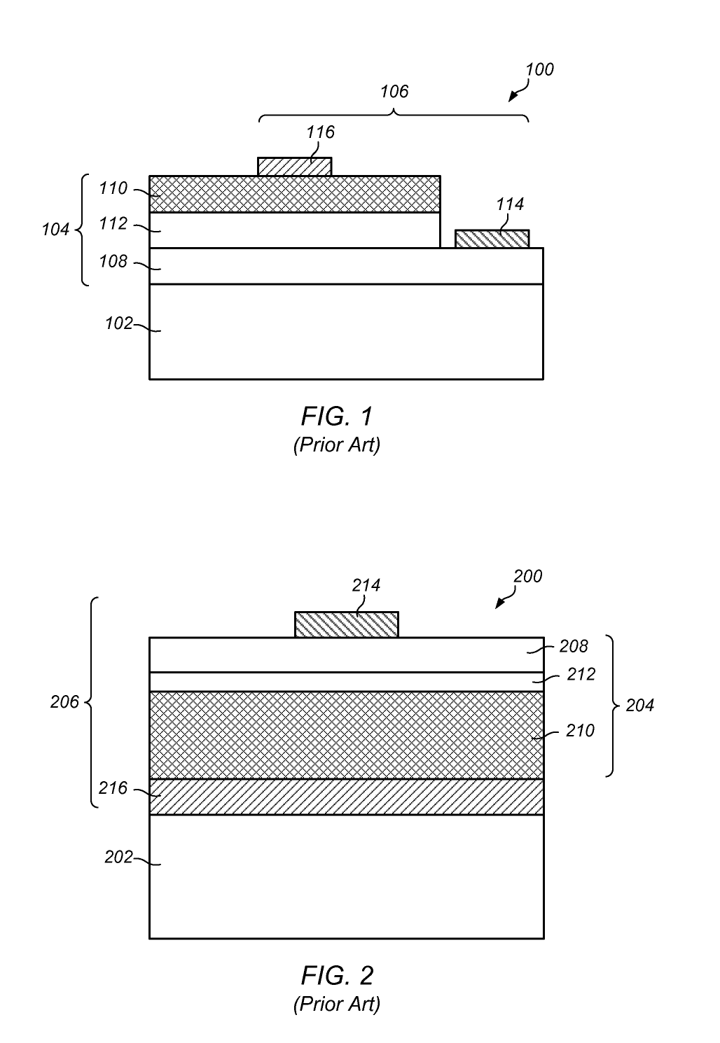

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

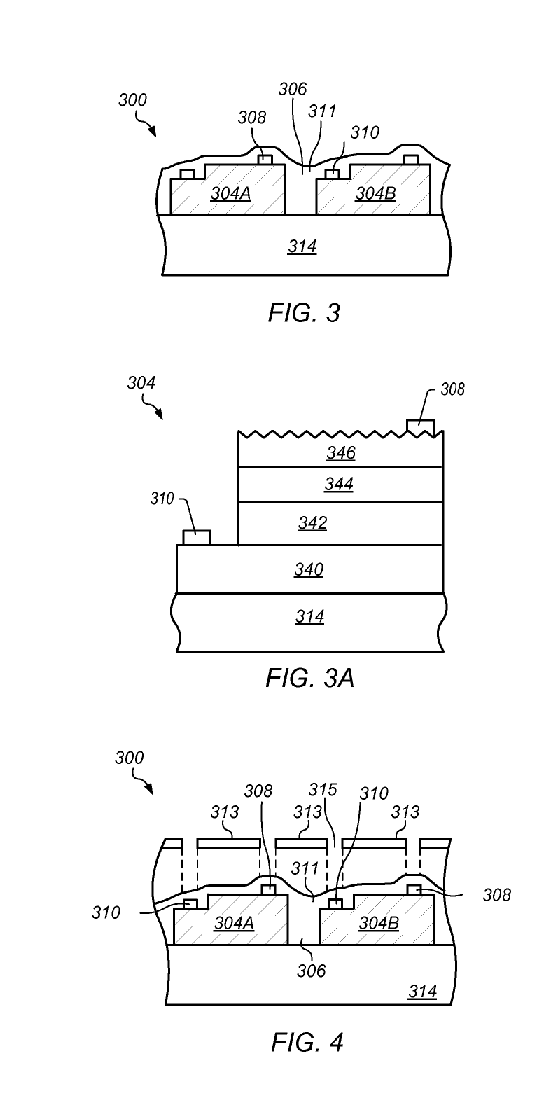

FIGS. 3-8 depict an embodiment of a process for forming n-side up light emitting diode (LED) array 300. In certain embodiments, the process for forming LED array 300 utilizes a dielectric material (e.g., a polymer material) to partially or fully fill gap 306 between two adjacent LEDs 304A, 304B on first substrate 314. LED array 300 is formed from multiple LED devices that produce significant amounts of light at relatively low current density. Low current density generates less heat and allows polymer materials to be used in forming the LED array.

First, an LED structure (not shown) is formed on first substrate 314. Next, a separating process (e.g., a laser etching method, a dicing or cutting saw, or an inductively coupled plasma reactive ion etching (ICP-RIE) method) is performed to separate the LED structure into a number of LEDs (e.g., LEDs 304A, 304B) separated by gaps (e.g., gap 306) on first substrate 314, as shown in FIG. 3. For simplicity in FIGS. 3 and 4, only two adjacent light emitting diodes including LED 304A and LED 304B and one gap 306 are shown and described. First substrate 314 may be, for example, a temporary substrate such as a sapphire substrate. The LED structure may be formed on first substrate 314 using conventional epitaxial techniques known in the art such as metal organic chemical vapor deposition (MOCVD). In certain embodiments, the LED structure includes gallium nitride (GaN) layers formed in multiple deposition processing steps to form GaN LEDs. For example, the LED structure may include a light emitting layer (e.g., a single quantum well layer or a multiple quantum well layer) sandwiched between n-type and p-type doped layers.

FIG. 3A depicts a representation of one possible embodiment of LED 304. In certain embodiments, LED 304 includes first doped layer 340, light emitting layer 342, second doped layer 344, and third doped layer 346. In certain embodiments, first doped layer 340, light emitting layer 342, second doped layer 344, and third doped layer 346 are GaN-based layers formed in multiple deposition processing steps.

In certain embodiments, light emitting layer 342 is a single quantum well layer or a multiple quantum well layer. In certain embodiments, first doped layer 340 is an n-type doped GaN layer, second doped layer 344 is a p-type doped AlGaN layer, and third doped layer 346 is a p-type doped GaN layer. In some embodiments, the surface of third doped layer 346 is partially roughened. In certain embodiments, LED 304 includes a first electrode (e.g., anode 308) formed on third doped layer 346 and a second electrode (e.g., cathode 310) formed on first doped layer 340. In some embodiments, an undoped layer (e.g., an undoped GaN layer) is formed on the bottom of first doped layer 340 (e.g., the undoped layer is formed between first doped layer 340 and first substrate 314.

As shown in FIG. 3, gap 306 is formed between first LED 304A and second LED 304B after separation of the LED structure. In certain embodiments, a dielectric material is deposited on and covers first LED 304A and second LED 304B and is fully filled into gap 306 to form first dielectric layer 311. In certain embodiments, first dielectric layer 311 includes polymer material, ceramic material, or combinations thereof. In some embodiments, first dielectric layer 311 is made of a photoresist (polymer) material such as polymethylglutarimide (PMGI) or SU-8. In some embodiments, first dielectric layer 311 is made of a ceramic material such as, but not limited to, silicon oxides, silicon nitrides, silicon oxynitrides, aluminum oxide, or other suitable ceramic or oxide materials.

In certain embodiments, the refractive index of first dielectric layer 311 ranges from 1 to 2.6 (between air and semiconductor) to enhance light extraction. Optical transparency of first dielectric layer 311 may be equal to or greater than about 90% (e.g., equal to or greater than about 99%). Typically, a thickness of first dielectric layer 311 measured on top of anode 308 is approximately 2 microns. In some embodiments, first dielectric layer 311 is pre-mixed with phosphor (about 30 weight percentage loading) to adjust the output light color if the first dielectric layer is a polymer. However, the relative dimension between polymer coating thickness and phosphor particle size should be coordinated. For example, when a thickness of first dielectric layer 311 at anode 308 is about 3 microns, proper phosphor particle size is approximately 3 microns or less.

Next, as shown in FIG. 4, patterned mask 313 is applied over the first dielectric layer 311. Mask 313 may have openings 315 at the locations of anodes 308 and cathodes 310 to allow the removal of first dielectric layer 311 thereon. In some embodiments, the dielectric removal process smoothes out the surface profile of first polymer layer 311. In some embodiments, the dielectric removal process allows the removal of first dielectric layer 311 over first LED 304A and second LED 304B to only leave first dielectric layer 311 in gap 306.

In certain embodiments, after the dielectric removal process and anodes 308 and cathodes 310 are exposed, a surface hydrophilic modification is performed on the dielectric surface (e.g., oxygen plasma for a polymer surface) to transform the originally hydrophobic surface into a hydrophilic surface. Therefore, a subsequently formed metal-based interconnect can have improved adhesion to first dielectric layer 311.

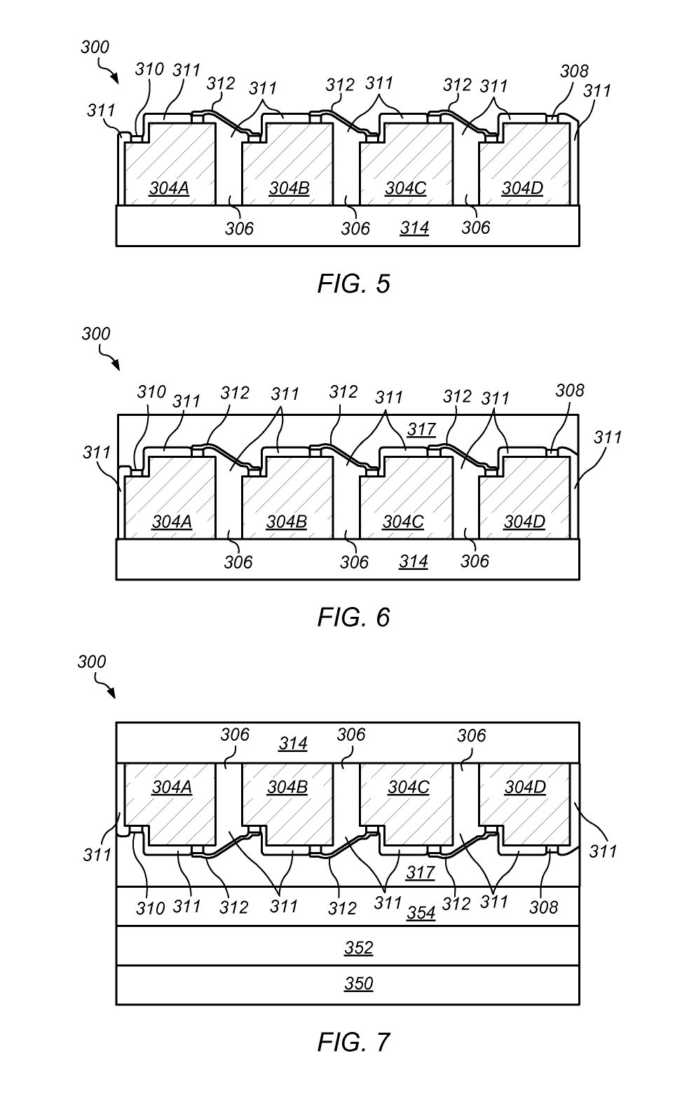

Subsequently, as shown in FIG. 5, series interconnects 312 are formed on top of first dielectric layer 311 to connect anodes 308 and cathodes 310 of adjacent LEDs. In certain embodiments, first dielectric layer 311 covers portions of LEDs 304 in addition to filling gaps 306 between the LEDs. In certain embodiments, the formation (deposition) of first dielectric layer 311 is controlled such that a thickness of the first dielectric layer above LEDs 304 is less than the height of anodes 308 and cathodes 310. In FIG. 5, four LEDs (LEDs 304A-D) are shown with three interconnects 312 between anodes 308 and cathodes 310 of the LEDs. Because of the relatively smooth surface profile of first dielectric layer 311, the subsequently formed metal-based interconnects 312 may have thin and smooth profiles.

Following formation of interconnects 312 on first dielectric layer 311, adhesive layer 317 may be formed over the interconnects and the first dielectric layer, as shown in FIG. 6. Adhesive layer 317 may be, for example, epoxy glue, wax, SOG (spin-on-glass), photo resist, monomer, polymer, or any glue type material known in the art for bonding GaN layers to silicon, silicon oxide, metal, ceramic, or polymer layers.

Adhesive layer 317 may be used to bond LED array 300 to second substrate 350, reflective layer 352, and/or insulating layer 354, as shown in FIG. 7. Second substrate 350 may be, for example, a silicon substrate or other suitable thermally conductive substrate. Second substrate 350 may be the permanent substrate for LED array 300. In certain embodiments, reflective layer 352 and/or insulating layer 354 are formed on a surface of second substrate 350 before being bonded to adhesive layer 317. Reflective layer 352 may include distributed Bragg reflector (DBR), omni-directional reflector (ODR), silver, aluminum, titanium, and/or other reflective conducting materials. Insulating layer 354 may include oxides, nitrides, and/or other suitable electrically insulating materials with high light transparency. When bonding LED array 300 to a permanent substrate (e.g., second substrate 350), a desired material of adhesive layer 317 is a monomer or uncross-linking polymer. After the bonding process, adhesive layer 317 may be cured to form polymer or cross-linked polymer to increase mechanical strength and chemical stability.

Following bonding to second substrate 350, first substrate 314 is removed from LED array 300, as shown in FIG. 8. First substrate 314 may be removed using, for example, a laser lift-off (LLO) process. Removal of first substrate 314 exposes the surface of LED array 300 opposite interconnects 312 and first dielectric layer 311 (e.g., the n-doped side of the LED array). In some embodiments, the exposed surfaces of LEDs 304 are at least partially roughened. For example, for an n-side GaN LED, an exposed undoped GaN layer or an exposed n-type doped GaN layer may be roughened using, for example, a wet etching process.

After exposure of the surface of LED array 300 opposite interconnects 312 and first dielectric layer 311, external electrical connections (either vertical or horizontal) may be made to one or more of LEDs 304 (e.g., the outermost LEDs, rightmost LED 304A and leftmost LED 304D, as depicted in FIG. 8). In certain embodiments of LED array 300, insulating layer 354 is used to inhibit reflective layer 352 from contacting anode 308 and/or cathode 310 during the bonding process due to non-uniformity in the thickness of adhesive layer 317 from, for example, non-uniform pressure being applied during the bonding process. There is, however, a potential problem with the presence of insulating layer 354, first dielectric layer 311, and/or adhesive layer 317 being located between LED 304 and reflective layer 352. The problem may be that, in some embodiments, insulating layer 354, first dielectric layer 311, and/or adhesive layer 317 may absorb or trap light and reduce the efficiency of light transmission in LED array 300.

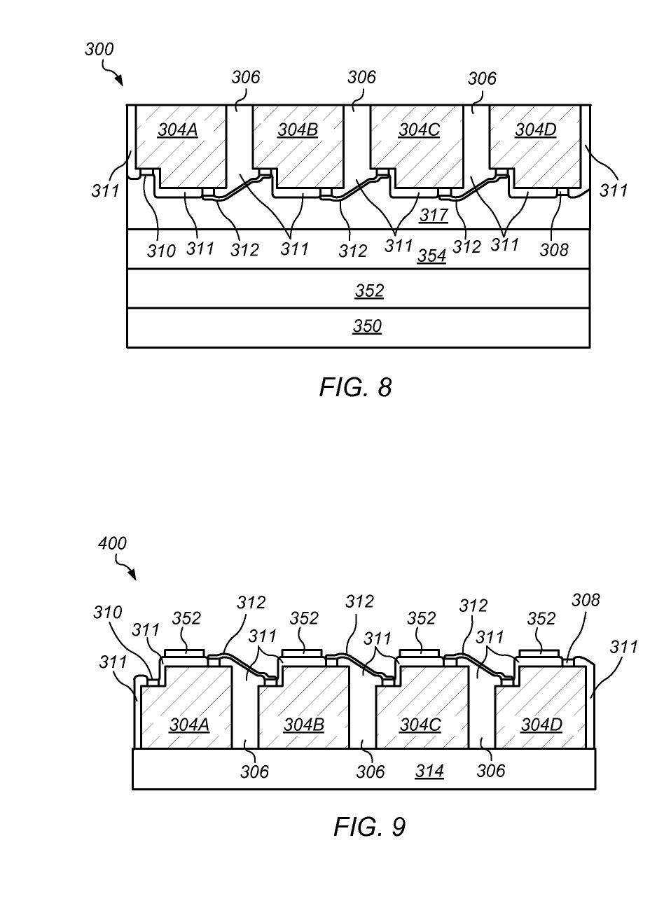

To overcome at least some of the problems with reduced light transmission efficiency, LED arrays may be formed that remove portions or all of insulating layer 354, first dielectric layer 311, and/or adhesive layer 317 from being between LED 304 and reflective layer 352. For example, reflective layer 352 may be directly formed on LEDs 304. FIG. 9 depicts a cross-sectional view of an embodiment of LED array 400 with a reflective layer formed over individual LEDs. Reflective layer 352 is formed over first dielectric layer 311 above LEDs 304A, 304B, 304C, and 304D following the formation of interconnects 312 and the first dielectric layer (described in FIGS. 3-5). Reflective layer 352 may include materials (such as a distributed Bragg reflector (DBR), an omni-directional reflector (ODR), silver, aluminum, titanium, or combinations thereof) that bond directly to first dielectric layer 311. Because reflective layer 352 is formed directly (e.g., deposited directly) on first dielectric layer 311, no adhesive layer or insulating layer is needed between the reflective layer and the first dielectric layer. In some embodiments, reflective layer 352 is formed during the same deposition process as interconnects 312 (e.g., the reflective layer and the interconnects may be formed at the same time if they are made of the same material).

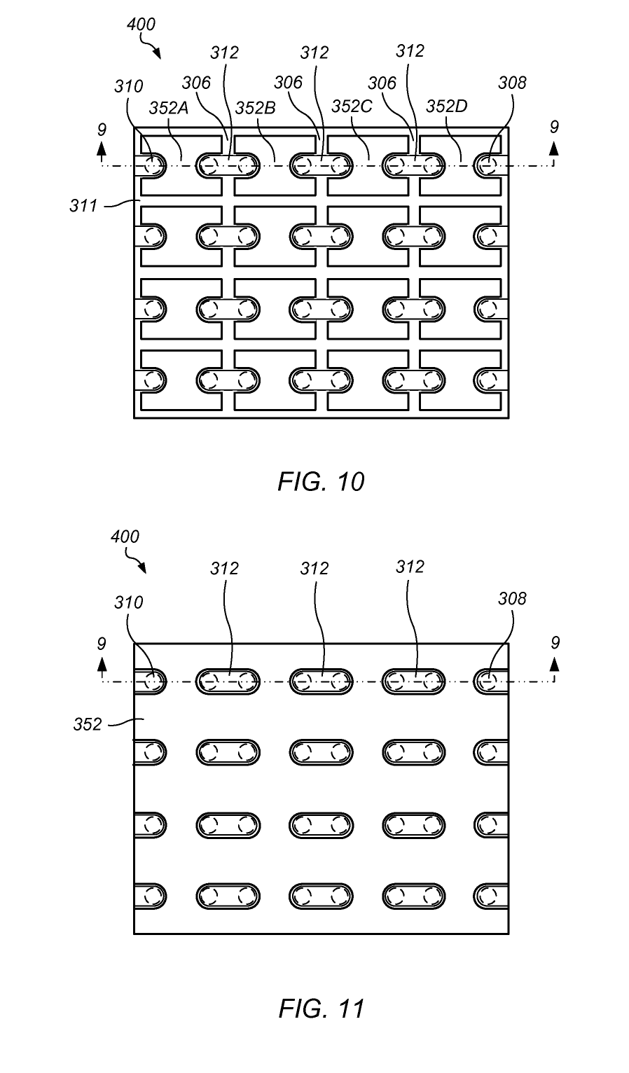

In certain embodiments, reflective layer 352 includes a plurality of separated, individual reflective layers. FIG. 10 depicts a schematic, top view of an embodiment of LED array 400 with separated, individual reflective layers formed over individual LEDs. The cutting plane line for FIG. 9 is shown in FIG. 10. As shown in FIG. 10, individual reflective layers 352A, 352B, 352C, and 352D are formed over LED array 400 with first dielectric layer 311 separating the reflective layers. First dielectric layer 311 may remain exposed in gaps 306 between reflective layers 352A, 352B, 352C, and 352D. Interconnects 312 connect anodes 308 and cathodes 310 of adjacent LEDs (located under reflective layers 352A, 352B, 352C, and 352D). Reflective layers 352A, 352B, 352C, and 352D are formed to be physically separated from and/or electrically insulated from interconnects 312 to inhibit electrical shorting between the reflective layers and the interconnects. In certain embodiments, reflective layers 352A, 352B, 352C, and 352D substantially cover their respective underlying LEDs.

In certain embodiments, reflective layer 352 includes a single, continuous reflective layer. FIG. 11 depicts a schematic, top view of an embodiment of LED array 400 with a single reflective layer formed over the plurality of LEDs in the LED array. The cutting plane line for FIG. 9 is shown in FIG. 11. As shown in FIG. 11, reflective layer 352 is formed as a single, continuous layer over LED array 400 with at least some physical separation and/or electrical insulation between the reflective layer and interconnects 312. Reflective layer 352 is physically separated from and/or electrically insulated from interconnects 312 to inhibit electrical shorting between the reflective layers and interconnects. Interconnects 312 connect anodes 308 and cathodes 310 of adjacent LEDs (located under reflective layer 352). In certain embodiments, reflective layer 352 substantially covers the underlying LEDs and first dielectric layer 311.

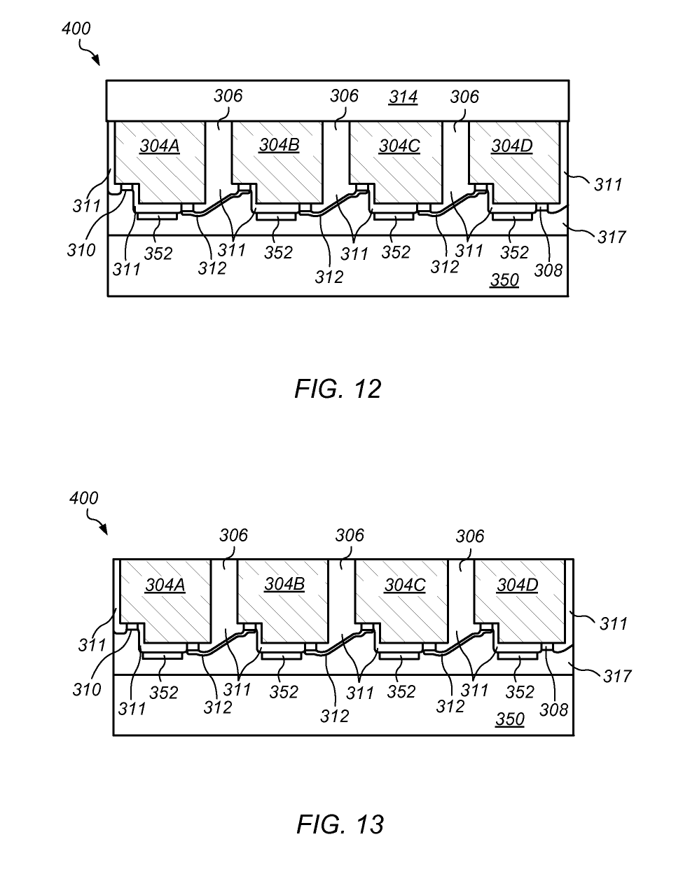

Following formation of reflective layer 352, adhesive layer 317 may be formed over the reflective layer and used to bond LED array 400 to second substrate 350, as shown in FIG. 12. Adhesive layer 317 may be, for example, epoxy glue, wax, SOG (spin-on-glass), photo resist, monomer, polymer, or any glue type material known in the art for bonding GaN layers to silicon, silicon oxide, metal, ceramic, or polymer layers. Second substrate 350 may be, for example, a silicon substrate or other suitable thermally conductive substrate. Second substrate 350 may be the permanent substrate for LED array 400. When bonding LED array 400 to a permanent substrate (e.g., second substrate 350), a desired material of adhesive layer 317 is a monomer or uncross-linking polymer. After the bonding process, adhesive layer 317 may be cured to form polymer or cross-linked polymer to increase mechanical strength and chemical stability. In some embodiments, adhesive layer 317 is replaced with a metal bonding layer, a eutectic bonding layer, or another bonding layer that can be used to bond second substrate 350 to reflective layer 352. In some embodiments, the permanent substrate (e.g., second substrate 350) is formed on reflective layer 352 using an in-situ method. The in-situ method may include any of physical vapor deposition, chemical vapor deposition, electroplating, electroless plating, or combinations thereof.

Following bonding to second substrate 350, first substrate 314 is removed from LED array 400, as shown in FIG. 13. First substrate 314 may be removed using, for example, a laser lift-off (LLO) process. Removal of first substrate 314 exposes the surface of LED array 400 opposite interconnects 312 and first dielectric layer 311 (e.g., the n-doped side of the LED array). In some embodiments, the exposed surfaces of LEDs 304 are at least partially roughened. For example, for an n-side GaN LED, an exposed undoped GaN layer or an exposed n-type doped GaN layer may be roughened using, for example, a wet etching process.

The process described in FIGS. 9-13 produces LED array 400 without the use of an insulating layer and an adhesive layer between reflective layer 352 and LEDs 304. Thus, LED array 400 provides an LED array with high light transmission efficiency and reduced light absorption or trapping. As shown in FIG. 13, LED array 400 has only one thin dielectric layer (first dielectric layer 311) between reflective layer 352 and LEDs 304. Thus, as compared to the embodiment of LED array 300 depicted in FIG. 8, the embodiment of LED array 400 depicted in FIG. 13 produces less light absorption or trapping between reflective layer 352 and LEDs 304 and produces higher light transmission efficiency.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a layer” includes a combination of two or more layers and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A light emitting diode array, comprising:
a first light emitting diode comprising a first electrode;
a second light emitting diode comprising a second electrode, wherein the second light emitting diode is separated from the first light emitting diode;
a first dielectric layer positioned between the first light emitting diode and the second light emitting diode, wherein a first portion of the first dielectric layer at least partially covers the first light emitting diode and a second portion of the first dielectric layer at least partially covers the second light emitting diode;
an interconnect located at least partially on the first dielectric layer, wherein the interconnect connects the first electrode to the second electrode;
a reflective layer formed over at least the first and second portions of the first dielectric layer; and
a permanent substrate coupled to a side of the light emitting diodes facing the reflective layer.

2. The array of claim 1, wherein the reflective layer is electrically insulated from the interconnect.

3. The array of claim 1, wherein the reflective layer is physically separated from the interconnect.

4. The array of claim 1, wherein the reflective layer comprises a first reflective layer formed over the first portion of the first dielectric layer and a second reflective layer formed over the second portion of the first dielectric layer, wherein the first and second reflective layers are separated.

5. The array of claim 4, wherein the first reflective layer and the second reflective layer are formed using a single process.

6. The array of claim 1, wherein the reflective layer comprises a single, continuous reflective layer.

7. The array of claim 1, wherein the first dielectric layer at least partially encapsulates the first and second light emitting diodes.

8. The array of claim 1, wherein the reflective layer and the interconnect are formed using a single process.

9. The array of claim 1, wherein the reflective layer directly bonds to the first dielectric layer.

10. The array of claim 1, wherein the first dielectric layer comprises an optical transparency equal to or greater than about 90%.

11. The array of claim 1, wherein a material of the first dielectric layer is selected from the group consisting of polymer, ceramic, and combinations thereof.

12. The array of claim 1, wherein the reflective layer comprises a distributed Bragg reflector (DBR), an omni-directional reflector (ODR), silver, aluminum, titanium, or combinations thereof.

13. The array of claim 1, wherein the array comprises an n-side up array.

14. A method for forming a light emitting diode array, comprising:
forming a first light emitting diode and a second light emitting diode on a temporary substrate;
forming a first dielectric layer between the first light emitting diode and the second light emitting diode, wherein a first portion of the first dielectric layer at least partially covers the first light emitting diode and a second portion of the first dielectric layer at least partially covers the second light emitting diode;
forming an interconnect between a first electrode on the first light emitting diode and a second electrode on the second light emitting diode, wherein the interconnect is formed at least partially on the first dielectric layer;
forming a reflective layer over at least the first and second portions of the first dielectric layer;
coupling a permanent substrate to a side of the light emitting diodes facing the reflective layer; and
removing the temporary substrate from the light emitting diodes.

15. The method of claim 14, wherein the reflective layer is electrically insulated from the interconnect.

16. The method of claim 14, wherein the reflective layer is physically separated from the interconnect.

17. The method of claim 14, wherein forming the reflective layer comprises forming a first reflective layer over the first portion of the first dielectric layer, and forming a second reflective layer over the second portion of the first dielectric layer, wherein the first and second reflective layers are separated.

18. The method of claim 17, further comprising forming the first reflective layer and the second reflective layer in a single process.

19. The method of claim 14, further comprising forming the reflective layer as a single, continuous reflective layer.

20. The method of claim 14, further comprising at least partially encapsulating the first and second light emitting diodes in the first dielectric layer.

21. The method of claim 14, further comprising forming the reflective layer and the interconnect in a single process.

22. The method of claim 14, further comprising directly depositing the reflective layer onto the first dielectric layer.

23. The method of claim 14, wherein the first light emitting diode and the second light emitting diode are separated by a gap.

24. The method of claim 23, further comprising forming the first dielectric layer by covering the light emitting diodes and filling the gap between the diodes with a dielectric material, patterning the dielectric material, and removing portions of the dielectric material according to the pattern to form the first dielectric layer.

25. The method of claim 14, wherein the temporary substrate is temporarily bonded to the light emitting diodes with an adhesive layer, and wherein the adhesive layer is removed when the temporary substrate is removed.

26. The method of claim 14, wherein the first dielectric layer comprises an optical transparency equal to or greater than about 90%.

27. The method of claim 14, wherein a material of the first dielectric layer is selected from the group consisting of polymer, ceramic, and combinations thereof.

28. The method of claim 14, wherein the reflective layer comprises a distributed Bragg reflector (DBR), an omni-directional reflector (ODR), silver, aluminum, titanium, or combinations thereof.
